(19) United States
(12) Patent Application Publication
(10) Pub. No.: US 2015/0177354 A1
(43) Pub. Date: Jun. 25, 2015

(54) MAGNETIC RESONANCE METHOD AND APPARATUS FOR OBTAINING A SCOUT SCAN OF A PATIENT CONTAINING A METALLIC IMPLANT

(71) Applicant: SIEMENS AKTIENGESELLSCHAFT, Muenchen (DE)

(72) Inventors: Theresa Bachschmidt, Erlangen (DE); Kecheng Liu, Solon, OH (US); Dominik Paul, Bubenreuth (DE)

(73) Assignee: SIEMENS AKTIENGESELLSCHAFT, Muenchen (DE)

(21) Appl. No.: 14/576,668

(22) Filed: Dec. 19, 2014

Related U.S. Application Data
(60) Provisional application No. 61/918,786, filed on Dec. 20, 2013.

(51) Int. Cl. G01R 33/565; G01R 33/48

(52) U.S. Cl. CPC G01R 33/56563; G01R 33/4818

(57) ABSTRACT

In a magnetic resonance method and apparatus, the magnetic resonance apparatus is operated according to a SEMAC (Slice Encoding for Metal Artifact Correction) sequence, and, before executing the SEMAC sequence, a scout sequence is implemented, which is a SEMAC sequence but without phase encoding in the direction perpendicular to the slice selection direction. The number of SEMAC coding steps can then be determined before executing the SEMAC sequence, so that an unnecessarily high number of SEMAC coding steps is avoided.

### RELATED APPLICATION

The present application claims the benefit of the filing date of Provisional Application Control No. 61/918,786, filed on Dec. 20, 2013, the contents of which are incorporated herein by reference.

### BACKGROUND OF THE INVENTION

1. Field of the Invention

The present invention concerns a method for implementing a scout scan of a patient who has a metallic implant, as well as a magnetic resonance apparatus for implementing such a method.

2. Description of the Prior Art

When obtaining magnetic resonance (MR) images (scans) of a patient who has a metallic implant, care must be taken to minimize, or correct, metal artifacts (distortions or occlusions) that occur as a result of the metal of the implant interacting with the magnetic fields that are used for generating the MR image.

A recently-developed magnetic resonance imaging pulse sequence for addressing this problem is known as the SEMAC (Slice Encoding for Metal Artifact Correction) method.

Details of this known method can be found, for example, in U.S. Pat. No. 7,928,729; United States Patent Application Publication No. 2014/0266191, “Compressive Slice Encoding for Metal Artifact Correction,” Lu et al., Proc. Intl. Soc. Mag. Reson. Med. Vol. 18 (2010) p. 3079; “The Optimization of SEMAC-VAT Technique for Magnetic Resonance Imaging of Total Knee Prosthesis: Comparison of 1.5T and 3T for Different Metal Materials,” Tao et al., Proc. Intl. Soc. Mag. Reson. Med. Vol. 21 (2013), p. 3488; and “New MR Imaging Methods for Metallic Implants in the Knee: Artifact Correction and Clinical Impact,” Chen et al., J. Mag. Res. Imaging, Vol. 33 (2011) United States patent practice. 1121-1127.

The known SEMAC method can be used for the suppression of metal artifacts in the slice direction (i.e., the same direction in which the imaging slice is selected) in spin echo (SE) based sequences, such as turbo spin echo (TSE). In the SEMAC method, an additional coding in the slice direction, which would not otherwise be present, is implemented in a conventional 2D imaging protocol. This additional coding is a phase coding, and is referred to as SEMAC coding. This SEMAC coding is composed of a number of phase coding steps, and the overall measurement (data acquisition) time increases linearly with the number of SEMAC steps. A suitable number of SEMAC steps, however, is necessary in order to completely resolve image artifacts (distortions) caused by the metallic implant in the patient, and therefore it is not possible to simply reduce the number of SEMAC coding steps in order to reduce the measurement time. Particularly in the case of T2-weighted TSE protocols with a long repetition time (TR), the total measurement time increases significantly. For example, in a T2-weighted TSE protocol that already includes 256 phase coding steps with a turbo factor of 8 and a repetition time of 4,000 ms, an acquisition time of 2 minutes, 8 seconds is required. If a SEMAC resolution of 16 steps is selected for use in such a protocol, the measurement time increases to over 34 minutes, which is significantly longer than is acceptable in most clinical or hospital environments.

A factor in the selection of the number of SEMAC steps that should be used is that the number of necessary SEMAC steps that are necessary in order to avoid metal artifacts in a particular examination are not known in advance, and therefore the selection of the number of SEMAC steps in the examination protocol is generally made in order to account for the worst case scenario. Moreover, the number of necessary SEMAC steps also depends on the position and orientation of the slice of the patient for which an image is to be acquired, in relation to the metal object (implant) in question. This means that the number of necessary SEMAC steps may vary from slice-to-slice.

### SUMMARY OF THE INVENTION

An object of the present invention is to provide a magnetic resonance imaging method and apparatus that make use of the SEMAC method for correcting or minimizing metal artifacts in the resulting MR image, wherein the number of SEMAC steps can be reduced, thereby shortening the overall measurement time.

This object is achieved in accordance with the present invention by a magnetic resonance imaging method and apparatus wherein a SEMAC scout scan is implemented before obtaining the actual SEMAC diagnostic data, and in this scout scan there is no phase coding in the k_{y} direction. This means that when the data from the scout scan in accordance with the invention are entered into a memory organized as k-space, which has orthogonal kₓ and k_{y} axes, which define locations (points) in k-space at which data entries will be made in the acquisition of diagnostic data according to a SEMAC method, no phase coding in the scout scan takes place along the k_{y} axis. The diagnostic data acquisition subsequently takes place such as by using an SE-based or a TSE-based data acquisition protocol. As used herein, “diagnostic data” or a “diagnostic data acquisition” mean the acquisition of MR image data of a suitable quality and resolution that enables the diagnostic question at issue to be answered by appropriate evaluation of the diagnostic image. By contrast, as is conventional, a “scout scan” (also called a “localizer scan”) is of a lower resolution or quality compared to a diagnostic image, and is used for planning the diagnostic data acquisition.

The data acquired in the scout scan according to the invention correspond to a projection or summation of all information that are included in the slice being imaged, on one line in k-space. In an embodiment of the invention, dependent on the signal value of this line, a decision can be made, either automatically or manually, as to how many SEMAC steps are necessary for that respective slice to be imaged free, or substantially free, of metal artifacts. Moreover, a determination can be made as to whether the SEMAC steps must be symmetrical, or whether symmetrical acquisition is even possible.

The scout acquisition can take place during the actual diagnostic data acquisition in a SEMAC protocol. For each SEMAC step, the central echo is acquired first, and is then evaluated in real time. If the signal represented by that central echo falls below a predetermined level, this SEMAC step is no longer acquired, meaning that the phase coding in the k_{y}-direction, which would otherwise take place in the SEMAC method, is not implemented for this particular step.

The ability to determine the necessary number of SEMAC steps in a SEMAC protocol has a number of advantages associated therewith. By being able to estimate how many SEMAC steps are required for a given examination, the data acquisition time for that examination can also be estimated. An optimal adaptation of the SEMAC protocol to the patient with a metal implant is thereby possible. This, in turn, allows time utilization to be optimized, because an unnecessarily large number of SEMAC steps are not implemented, because it is known in advance that such a large number of steps are not necessary in order to achieve the desired metal artifact correction. The scan can be implemented with confidence that the selected number of SEMAC steps will not be too few in order to achieve the desired metal artifact correction, thereby avoiding repeated scans of the same patient due to inadequate metal artifact correction in an initial scan.

The present invention also encompasses a non-transitory, computer-readable data storage medium that is encoded with programming instructions that, when the storage medium is loaded into a control computer of a magnetic resonance apparatus, cause the magnetic resonance apparatus to be operated according to the method described above.

### BRIEF DESCRIPTION OF THE DRAWINGS

FIG. 1 schematically illustrates the known SEMAC method, taken from FIG. 5 in aforementioned U.S. Pat. No. 7,928,729.

FIG. 2 schematically illustrates a magnetic resonance apparatus in accordance with the invention, suitable for implementing the method in accordance with the invention.

FIG. 3 schematically illustrates a scout scan in accordance with the invention.

FIG. 4 schematically illustrates the image data in respective lines of k-space in a conventional SEMAC sequence.

FIG. 5 schematically illustrates the filling of a single line of k-space in the SEMAC-based scout scan in accordance with the present invention.

### DESCRIPTION OF THE PREFERRED EMBODIMENTS

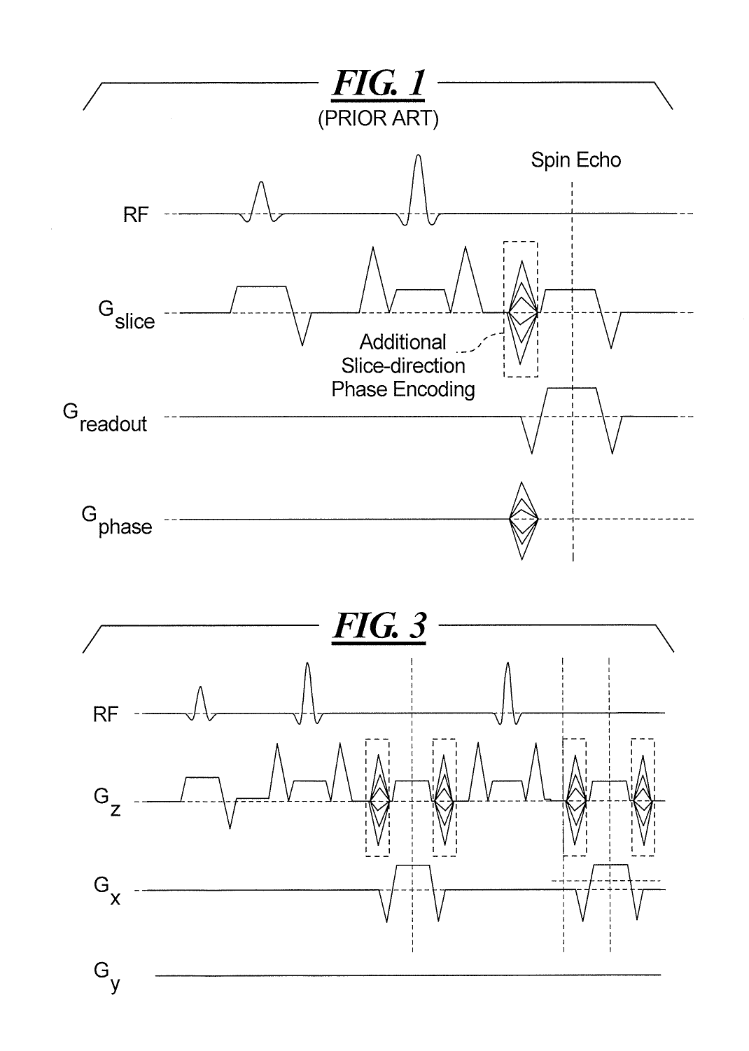

FIG. 1 schematically illustrates a conventional SEMAC method, wherein nuclear spins of an examination subject, who has a metallic implant, are excited in a known manner in a spin echo sequence by one or more RF excitation pulses. The excited nuclear spins are confined to a selected slice by a slice-selection gradient G_{slice}, followed by readout under a readout gradient G_{readout} and phase encoding by a phase-encoding gradient Gₚₕₐₛₑ. As described above, in the SEMAC method, an additional slice-direction phase encoding takes place, in the block outlined with a dashed line. This additional slice-direction phase encoding takes place in multiple steps, called SEMAC steps. The basic SEMAC method is based on the technique known as view angle tilting (VAT), wherein a gradient is applied on the slice selection axis during readout, with an amplitude that is equal to that of the slice selection gradient. If readout takes place, for example, along the z-direction of a Cartesian coordinate system, and readout take place along the x-direction, then the slice is effectively viewed at an angle that is the arctangent of the ratio of the gradient applied along the z-axis and the gradient applied along the x-axis. This causes shifts in the slice-selection direction to exactly cancel shifts in the readout direction, as stated in the aforementioned U.S. Pat. No. 7,928,729, from which FIG. 1 is taken.

In the SEMAC method, the VAT sequence is extended by the additional phase encoding that takes place in the slice selection direction, as shown in FIG. 1. The distorted excitation profiles (through-plane distortions) caused by the presence of the metal implant are corrected by this additional phase encoding.

Conventionally, the number of such additional phase encoding steps that is necessary in order to satisfactorily correct or resolve the image artifacts caused by the metal implant are not known in advance, and therefore the number of such SEMAC coding steps is generally selected to account for the worst case scenario, and is thus often more than is strictly necessary to avoid artifacts in an image obtained from a patient with a particular implant.

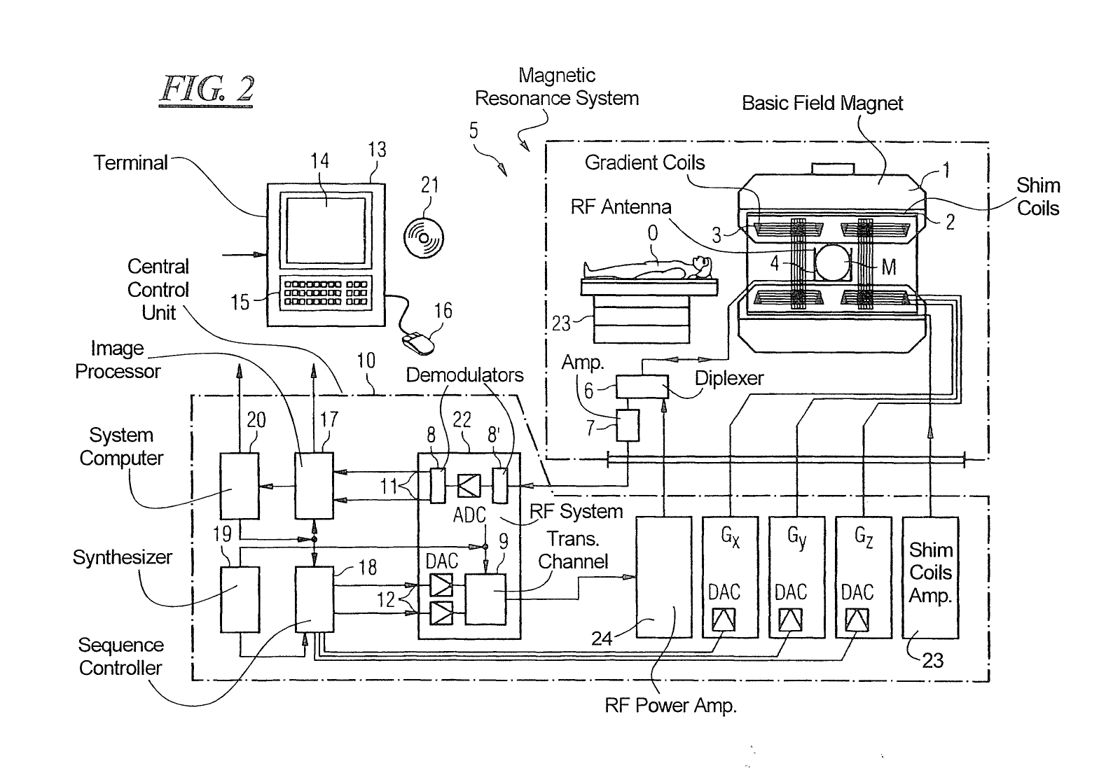

A schematic illustration of the basic design of a magnetic resonance apparatus that is suitable for operation in accordance with the present invention is shown in FIG. 2. The basic operation will be explained below, and this basic operation can be modified in accordance with the present invention by suitable programming of the system computer 20.

As noted above, FIG. 1 is a schematic depiction of a magnetic resonance system 5 (a magnetic resonance imaging or magnetic resonance tomography apparatus). A basic field magnet 1 generates a temporally constant, strong magnetic field for polarization or alignment of the nuclear spins in an examination region of a subject O, for example of a part of a human body that is to be examined that—lying on a table 23—is slid continuously into the magnetic resonance system 5. The high homogeneity of the basic magnetic field that is required for the nuclear magnetic resonance measurement is defined in a typically spherical measurement volume M, through which the parts of the human body that are to be examined are slid continuously. Shim plates made of ferromagnetic material are attached at suitable points to support the homogeneity requirements, and in particular to eliminate temporally invariable influences. Temporally variable influences are eliminated by shim coils 2 operate by a shim coils amplifier 23.

A cylindrical gradient field system 3 composed of three sub-windings is situated in the basic field magnet 1. Each sub-winding is supplied with current by an amplifier to generate a linear (also temporally variable) gradient magnetic field in the respective directions of a Cartesian coordinate system. The first sub-winding of the gradient field system 3 thereby generates a gradient Gₓ in the x-direction, the second sub-winding generates a gradient G_{y} in the y-direction, and the third sub-winding generates a gradient G_{z} in the z-direction. Each amplifier includes a digital/analog converter that is activated by a sequence controller 18 for accurately-timed generation of gradient pulses.

Situated within the gradient field system 3 are one or more radio-frequency antennas 4 that convert the radio-frequency pulses emitted by a radio-frequency power amplifier 24 into an alternating magnetic field for excitation of the nuclei and alignment of the nuclear spins of the subject O to be examined, or of the region of the subject O that is to be examined. Each radio-frequency antenna 4 has one or more RF transmission coils and one or more RF reception coils in the form of an annular (preferably linear or matrix-like) arrangement of component coils. The alternating field emanating from the precessing nuclear spins—normally the nuclear spin echo signals caused by a pulse sequence composed of one or more radio-frequency pulses and one or more gradient pulses—is also converted by the RF reception coils of the respective radio-frequency antenna 4 into a voltage (measurement signal) which is supplied via an amplifier 7 to a radio-frequency reception channel 8 of a radio-frequency system 22. The radio-frequency system 22, which is part of a control device 10 of the magnetic resonance system 5, furthermore has a transmission channel 9 in which the radio-frequency pulses are generated for the excitation of the nuclear magnetic resonance. The respective radio-frequency pulses are digitally represented in the sequence controller as a series of complex numbers based on a pulse sequence provided by the system computer 20. This number sequence is supplied as a real part and an imaginary part to a digital/analog converter in the radio-frequency system 22 via respective inputs 12, and from the digital/analog converter to the transmission channel 9. In the transmission channel 9, the pulse sequences are modulated on a radio-frequency carrier signal whose base frequency corresponds to the resonance frequency of the nuclear spins in the measurement volume.

Switching from transmission operation to reception operation takes place via a transmission/reception diplexer 6. The RF transmission coils of the radio-frequency antenna(s) 4 radiate(s) the radio-frequency pulses for excitation of the nuclear spins into the measurement volume M and scans resulting echo signals via the RF reception coil(s). The correspondingly acquired magnetic resonance signals are phase-sensitively demodulated to an intermediate frequency in a reception channel 8′ (first demodulator) of the radio-frequency system 22, digitized in an analog/digital converter (ADC) and output via the output 11. This signal is further demodulated to a frequency of zero. The demodulation to a frequency of zero and the separation into real part and imaginary part occurs in a second demodulator 8 after the digitization in the digital domain. An MR image or a spectroscopy information is reconstructed by an image computer 17 from the measurement data obtained in such a manner via an output 11. The administration of the measurement data, the image data and the control programs takes place via the system computer 20. Based on a specification with control programs, the sequence controller 18 monitors the generation of the respective desired pulse sequences and the corresponding scanning of k-space. In particular, the sequence controller 18 thereby controls the accurately-timed switching of the gradients, the emission of the radio-frequency pulses with defined phase amplitude, and the reception of the magnetic resonance signals. The time base for the radio-frequency system 22 and the sequence controller 18 is provided by a synthesizer 19. The selection of corresponding control programs to generate a spectroscopy information or an MR image, and the presentation of the obtained frequency spectrum or of the generated MR image, take place via a terminal 13 that has a keyboard 15, a mouse 16 and a monitor 14.

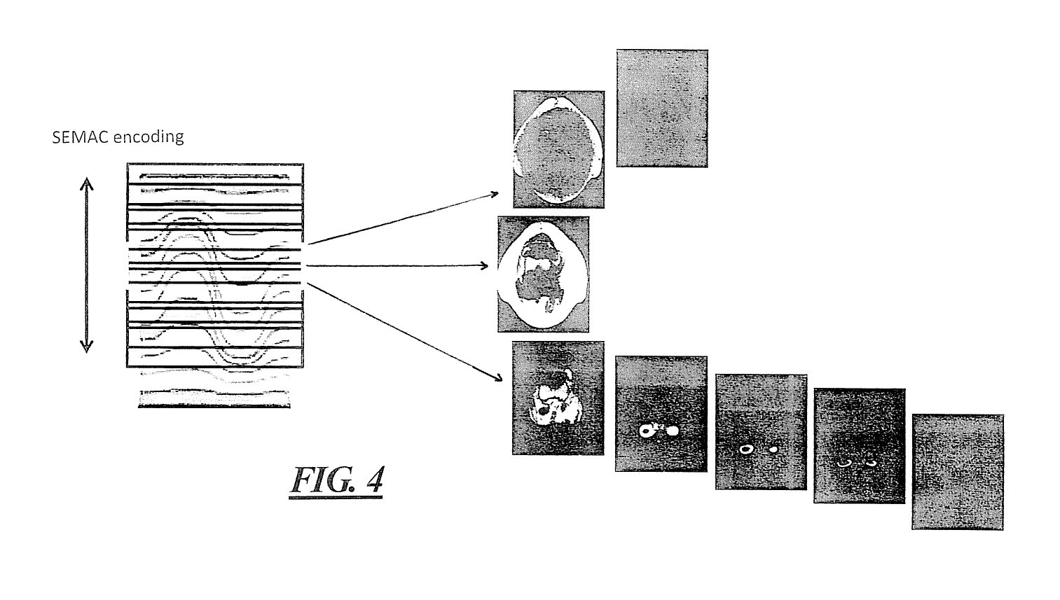

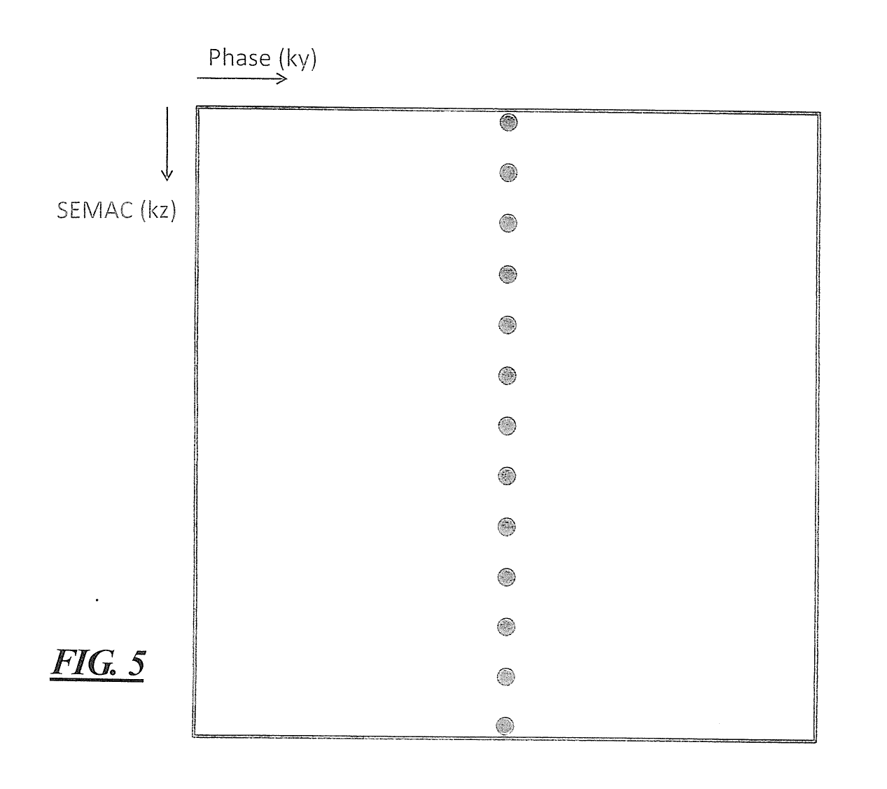

FIG. 3 shows the SEMAC-based scout sequence in accordance with the invention wherein, as can be seen in comparison with FIG. 1, there is no phase coding in the y-direction. The effect of this can be seen from FIGS. 4 and 5. FIG. 4 shows an example of the slices that are present in SEMAC coding of k-space, and FIG. 5 shows the fact that only one line of k-space data exists in the scout sequence according to the invention. This one line represents one image, or set of images, of the type shown in FIG. 4, and thus permits an easy and rapid evaluation of the number of SEMAC steps that should be employed. As noted above, the data acquired in the scout correspond to a projection or summation of all information included in the slice along one line of k-space. Dependent on the signal value of this line, a decision can be made as to how many SEMAC steps are necessary for the respective slice. It can also be determined whether the SEMAC steps must be symmetrical, or whether such a symmetrical acquisition is even possible.

The scout acquisition can take place during the actual data acquisition of a SEMAC protocol, as shown in FIG. 3. For each SEMAC step, the central echo is acquired first, and is then evaluated in real time. If the signal is below a predetermined level, this SEMAC step is no longer acquired, meaning that the phase coding in the k_{y} direction is not implemented for this step.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for operating a magnetic resonance apparatus, comprising:
from a control unit, operating a magnetic resonance data acquisition unit to execute a SEMAC (Slice Encoding for Metal Artifact Correction) sequence, said magnetic resonance data acquisition unit comprising a gradient system and, in said SEMAC sequence, operating said gradient coil system to generate a slice selection gradient in a first direction and a phase-encoding gradient in a second direction, orthogonal to said first direction;
prior to operating said magnetic resonance data acquisition unit to execute said SEMAC sequence, operating said magnetic resonance data acquisition unit to implement a scout sequence that comprises said SEMAC sequence but with said gradient coil system operated to produce no phase encoding in said second direction; and
entering magnetic resonance data acquired in said scout sequence into an electronic memory organized as k-space to produce a data file in k-space in which only one line of k-space is filled with said MR data.

2. A method as claimed in claim 1 comprising, in a computer, accessing said memory and automatically evaluating a signal level of said MR data in said one line of k-space, and automatically determining a number of SEMAC steps to be executed in said SEMAC sequence dependent on a relationship of said signal level to a predetermined signal level.

3. A method as claimed in claim 2 comprising making said determination in said computer in real time with operation of said magnetic resonance data acquisition unit to execute said SEMAC sequence.

4. A method as claimed in claim 1 comprising acquiring said magnetic resonance data in said SEMAC sequence according to a spin echo data acquisition technique.

5. A method as claimed in claim 1 comprising acquiring said magnetic resonance data in said SEMAC sequence according to a turbo spin echo data acquisition technique.

6. A magnetic resonance apparatus comprising:
a magnetic resonance data acquisition unit comprising a gradient coil system;
a control unit configured to operate the magnetic resonance data acquisition unit to execute a SEMAC (Slice Encoding for Metal Artifact Correction) sequence, including operating said gradient coil system to generate a slice selection gradient in a first direction and a phase-encoding gradient in a second direction, orthogonal to said first direction;
said control unit being configured to operate said magnetic resonance data acquisition unit, prior to operating said magnetic resonance data acquisition unit to execute said SEMAC sequence, to implement a scout sequence that comprises said SEMAC sequence but with said gradient coil system operated to produce no phase encoding in said second direction;
an electronic memory organized as k-space; and
said control unit being configured to enter magnetic resonance data acquired in said scout sequence into said electronic memory organized as k-space to produce a data file in k-space in which only one line of k-space is filled with said MR data.

7. An apparatus as claimed in claim 6 comprising a computer configured to access said memory and automatically evaluate a signal level of said MR data in said one line of k-space, and to automatically determine a number of SEMAC steps to be executed in said SEMAC sequence dependent on a relationship of said signal level to a predetermined signal level.

8. An apparatus as claimed in claim 7 wherein said computer is configured to make said determination in said computer in real time with operation of said magnetic resonance data acquisition unit to execute said SEMAC sequence.

9. An apparatus as claimed in claim 6 wherein said control unit is configured to operate said magnetic resonance data acquisition unit to acquire said magnetic resonance data in said SEMAC sequence according to a spin echo data acquisition technique.

10. An apparatus as claimed in claim 6 said control unit is configured to operate said magnetic resonance data acquisition unit to acquire said magnetic resonance data in said SEMAC sequence according to a turbo spin echo data acquisition technique.

11. A non-transitory, computer-readable data storage medium encoded with programming instructions, said data storage medium being loaded into a control computer of a magnetic resonance apparatus that comprises a magnetic resonance data acquisition unit having a gradient coil system, and said programming instructions causing said control computer to:
operate the magnetic resonance data acquisition unit to execute a SEMAC (Slice Encoding for Metal Artifact Correction) sequence, including operating said gradient coil system to generate a slice selection gradient in a first direction and a phase-encoding gradient in a second direction, orthogonal to said first direction;
prior to operating said magnetic resonance data acquisition unit to execute said SEMAC sequence, operate said magnetic resonance data acquisition unit to implement a scout sequence that comprises said SEMAC sequence but with said gradient coil system operated to produce no phase encoding in said second direction; and
enter magnetic resonance data acquired in said scout sequence into an electronic memory organized as k-space to produce a data file in k-space in which only one line of k-space is filled with said MR data.

12. A storage medium as claimed in claim 11 wherein said programming instructions cause said control computer to access said memory and automatically evaluate a signal level of said MR data in said one line of k-space, and automatically determine a number of SEMAC steps to be executed in said SEMAC sequence dependent on a relationship of said signal level to a predetermined signal level.

13. A storage medium as claimed in claim 12 wherein said programming instructions cause said control to make said determination in said computer in real time with operation of said magnetic resonance data acquisition unit to execute said SEMAC sequence.

14. A storage medium as claimed in claim 11 wherein said programming instructions cause said control computer to operate said magnetic resonance data acquisition unit to acquire said magnetic resonance data in said SEMAC sequence according to a spin echo data acquisition technique.

15. A storage medium as claimed in claim 11 wherein said programming instructions cause said control computer to operate said magnetic resonance data acquisition unit to acquire said magnetic resonance data in said SEMAC sequence according to a turbo spin echo data acquisition technique.
